(19) United States
(12) Patent Application Publication
(10) Pub. No.: US 2026/0121318 A1
(43) Pub. Date: Apr. 30, 2026

(54) POWER SEMICONDUCTOR DEVICE AND METHOD OF MANUFACTURING THE SAME

(71) Applicant: FUJI ELECTRIC CO., LTD., Kawasaki-shi (JP)

(72) Inventors: Ryoichi KATO, Matsumoto-city (JP); Koji OSAKI, Matsumoto-city (JP); Naoyuki KANAI, Matsumoto-city (JP)

(73) Assignee: FUJI ELECTRIC CO., LTD., Kawasaki-shi (JP)

(21) Appl. No.: 19/433,617

(22) Filed: Dec. 26, 2025

Related U.S. Application Data
(63) Continuation of application No. PCT/JP2024/045896, filed on Dec. 25, 2024.

(30) Foreign Application Priority Data
Mar. 15, 2024 (JP) 2024-041063

(51) Int. Cl. H01R 12/71; H10W 70/05; H10W 74/10; H10W 90/00; H10W 90/10

(52) U.S. Cl. CPC H01R 12/718; H10W 70/093; H10W 90/10; H10W 90/401; H10W 74/114

(57) ABSTRACT

A power semiconductor device, including: a power semiconductor element mounted on a principal surface of an insulating circuit substrate; a wiring substrate facing the principal surface, and including a plurality of wiring pattern layers each electrically connected to the power semiconductor element or the insulating circuit substrate; a plurality of terminals electrically connected to the power semiconductor element, each terminal having a first end and a second end; an encapsulating resin encapsulating the power semiconductor element, the insulating circuit substrate, the wiring substrate, and the second ends of the terminals with the first ends thereof exposed; and a plurality of resin holders each disposed around an outer periphery of a part of one of the terminals, and having a lower surface in contact with the wiring substrate. The terminals are all directly connected to the wiring substrate, and are all electrically connected to the plurality of wiring pattern layers.

### CROSS-REFERENCE TO RELATED APPLICATION(S)

This application is a continuation application of International Application PCT/JP2024/045896 filed on Dec. 25, 2024, which designated the U.S., and claims priority to Japanese Patent Application 2024-041063, filed on Mar. 15, 2024, the entire contents of which are incorporated herein by reference.

### BACKGROUND OF THE INVENTION

### 1. Field of the Invention

The embodiment discussed herein relates to a power semiconductor device and a method of manufacturing the same.

### 2. Background of the Related Art

A power semiconductor device has been proposed in which terminals project from the upper surface of the device for miniaturization or other reasons (for example, see Patent Literatures (1) to (7) listed below). For example, as disclosed in Patent Literatures (5) to (7), techniques have been proposed in which transfer molding is performed with resin sleeves fitted to the upper ends of electrode terminals erected on a circuit pattern on the upper surface of an insulating substrate, and external terminals are inserted through the exposed openings of the sleeves into contact with the electrode terminals.

(1) Japanese Laid-open Patent Publication No. 2019-207897

(2) Japanese Laid-open Patent Publication No. 2016-197932

(3) Japanese Laid-open Patent Publication No. 2018-195714

(4) International Publication Pamphlet No. WO 2022/259824

(5) Japanese Laid-open Patent Publication No. 2013-30792

(6) Japanese Laid-open Patent Publication No. 2011-49343

(7) Japanese Laid-open Patent Publication No. 2010-129818

### SUMMARY OF THE INVENTION

According to an aspect, there is provided a power semiconductor device, including: a power semiconductor element; an insulating circuit substrate having a principal surface on which the power semiconductor element is mounted; a wiring substrate disposed to face the principal surface of the insulating circuit substrate, the wiring substrate including a plurality of wiring pattern layers each electrically connected to the power semiconductor element or to the insulating circuit substrate; a plurality of terminals electrically connected to the power semiconductor element, each terminal having a first end and a second end; an encapsulating resin encapsulating the power semiconductor element, the insulating circuit substrate, the wiring substrate, and a part of each of the plurality of terminals with the first end of each of the plurality of terminals exposed; and a plurality of resin holders respectively for the plurality of terminals, each resin holder being disposed around a part of an outer periphery of the corresponding one of the plurality of terminals, and having a lower surface in contact with the wiring substrate, wherein all of the plurality of terminals are directly connected to the wiring substrate, and are electrically connected to the plurality of wiring pattern layers.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a top view illustrating an example of a power semiconductor device according to an embodiment;

FIG. 2 is a sectional view illustrating the example of the power semiconductor device according to the embodiment;

FIG. 3 is an enlarged side view of a connection portion between a terminal and a wiring substrate;

FIG. 4 is a top view of the terminal and a resin holder;

FIG. 5 is a top view of the terminal and the resin holder in the case where the rein holder is formed in a truncated conical shape;

FIG. 6 is a sectional view illustrating terminals and a part of the wiring substrate at the time of transfer molding;

FIG. 7 illustrates how much force is applied by an upper mold onto a resin holder;

FIG. 8 illustrates examples of a plurality of taper angles and the appearances of the resin holder at the respective taper angles;

FIGS. 9A and 9B illustrate simulation results of the relationships between taper angle and surface pressure and between taper angle and reaction force; and 2

FIG. 10 is a flowchart illustrating an example of a method of manufacturing a power semiconductor device.

### DETAILED DESCRIPTION OF THE INVENTION

Hereinafter, an embodiment of the present disclosure will be described with reference to the drawings.

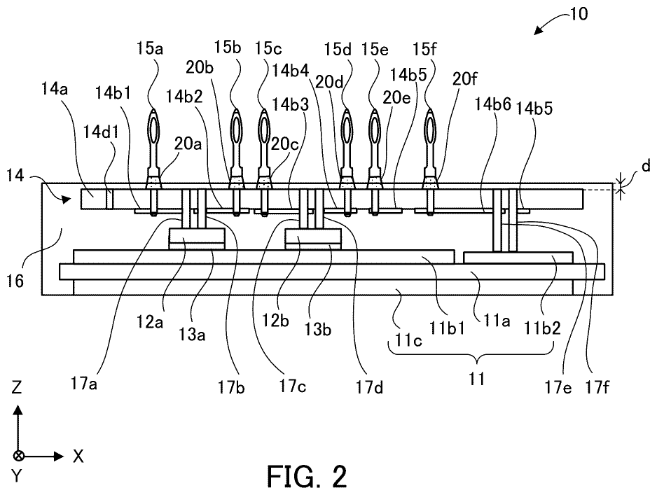

In the following description, the terms “front surface” and “upper surface” refer to an X-Y plane facing upward (+Z direction) in a power semiconductor device 10 of FIG. 2 and others. Similarly, the term “up” refers to an upward direction (+Z direction) in the power semiconductor device 10 of FIG. 2 and others. The terms “rear surface” and “lower surface” refer to an X-Y plane facing downward (−Z direction) in the power semiconductor device 10 of FIG. 2 and others. Similarly, the term “down” refers to a downward direction (−Z direction) in the power semiconductor device 10 of FIG. 2 and others. The same definition of directions applies to other drawings, as appropriate. The terms “front surface”, “upper surface”, “up”, “rear surface”, “lower surface”, “down”, and “side surface” are used merely for convenience in describing relative positional relationships, and do not limit the technical concept of the embodiment. For example, the terms “up” and “down” are not necessarily related to the vertical directions to the ground. That is, the “up” and “down” directions are not limited to those related to the direction of gravity.

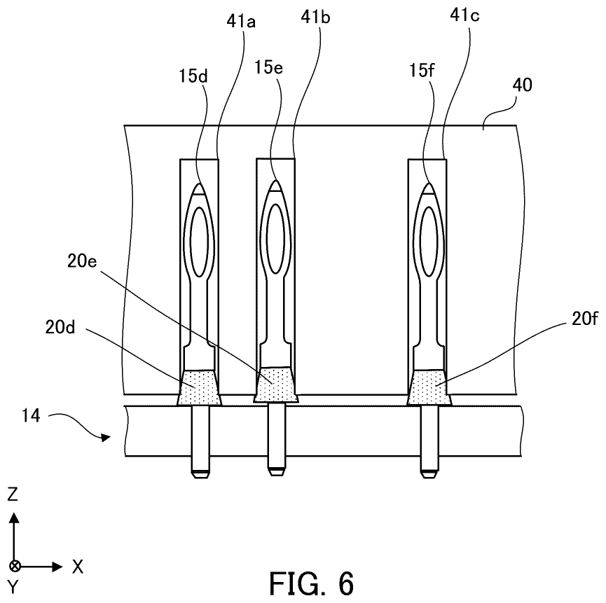

The power semiconductor device 10 described below is configured such that a plurality of terminals are mounted with high positional accuracy. If the positional accuracy of the terminals is poor, the terminals are not properly inserted into a mold during molding using an encapsulating resin. If portions (for example, recesses 41a, 41b, and 41c of an upper mold 40 in FIG. 6 to be described later) of the mold in which the terminals are placed are enlarged to accommodate positional errors, problems such as resin burrs and resin leakage may occur, so that the appearance of the device may fail to meet a product shipment level. In addition, in the case where the terminals of the power semiconductor device 10 are to be inserted into an external printed circuit board or the like, such poor positional accuracy may prevent proper insertion of the terminals. For the above reasons, it is important to improve the positional accuracy of the terminals.

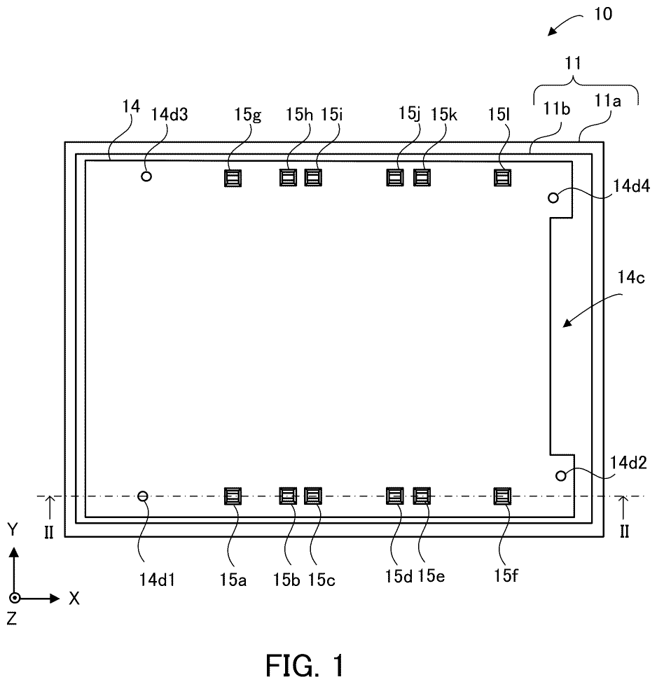

FIG. 1 is a top view illustrating an example of the power semiconductor device according to an embodiment. FIG. 2 is a sectional view illustrating the example of the power semiconductor device according to the embodiment. The sectional view of FIG. 2 is a view taken along the line II-II of FIG. 1. In FIG. 1, an encapsulating resin 16 is not illustrated.

The power semiconductor device 10 includes an insulating circuit substrate 11, power semiconductor elements 12a and 12b, a wiring substrate 14, a plurality of terminals 15a, 15b, 15c, 15d, 15e, 15f, 15g, 15h, 15i, 15j, 15k, and 15l, and the encapsulating resin 16.

The insulating circuit substrate 11 has a rectangular shape in plan view. The insulating circuit substrate 11 includes an insulating plate 11a, a circuit pattern 11b (including circuit patterns 11b1 and 11b2) provided on the front surface (upper surface) of the insulating plate 11a, and a metal plate 11c provided on the rear surface (lower surface) of the insulating plate 11a.

The insulating plate 11a has a rectangular shape in plan view. Corner portions of the insulating plate 11a may be R-chamfered or C-chamfered. The insulating plate 11a is made of a ceramic material having good thermal conductivity. The ceramic material contains, for example, aluminum oxide, aluminum nitride, or silicon nitride as a main component.

The edges of the circuit pattern 11b facing the outer peripheral edges of the insulating plate 11a are preferably aligned with the edges of the metal plate 11c facing the outer peripheral edges of the insulating plate 11a in plan view. Therefore, in the insulating circuit substrate 11, a stress balance with the metal plate 11c on the rear surface of the insulating plate 11a is maintained, so that excessive warpage, cracking, and other damage of the insulating plate 11a are suppressed.

The circuit pattern 11b is made of a metal having excellent conductivity. Such a metal is, for example, copper, aluminum, or an alloy containing at least one of these metals.

The circuit pattern 11b is obtained by forming a metal plate on the front surface of the insulating plate 11a and performing etching or another processing on the metal plate. Alternatively, the circuit pattern 11b cut out from a metal plate in advance may be press-bonded to the front surface of the insulating plate 11a. The number of circuit patterns 11b, and their shapes, sizes, and others may be selected as appropriate.

The metal plate 11c has a rectangular shape in plan view. Further, corner portions thereof may be R-chamfered or C-chamfered. The metal plate 11c is smaller in size than the insulating plate 11a, and is formed on the entire surface of the insulating plate 11a except for the edge portion thereof. The metal plate 11c is mainly made of a metal having excellent thermal conductivity. The metal is, for example, copper, aluminum, or an alloy containing at least one of these metals.

For example, a direct copper bonding (DCB) substrate or an active metal brazed (AMB) substrate may be used as the insulating circuit substrate 11.

The power semiconductor elements 12a and 12b are mounted on a principal surface of the insulating circuit substrate 11. The front surface (upper surface) of the circuit pattern 11b serves as the principal surface of the insulating circuit substrate 11. As illustrated in FIG. 2, the power semiconductor elements 12a and 12b are mechanically and electrically connected to the front surface of the circuit pattern 11b1 by lower solders 13a and 13b.

The power semiconductor elements 12a and 12b include switching elements made of silicon, silicon carbide, or gallium nitride. Each switching element is, for example, an insulated gate bipolar transistor (IGBT) or a power metal-oxide-semiconductor field-effect transistor (MOSFET). The power semiconductor elements 12a and 12b may be reverse-conducting (RC)-IGBTs. The RC-IGBT integrates the functions of an IGBT and a freewheeling diode (FWD). The power semiconductor elements 12a and 12b may be power MOSFETs made of silicon carbide. The body diode of a power MOSFET (including those made of silicon carbide) may serve the same function as the FWD of an RC-IGBT.

Although not illustrated, main electrodes and control electrodes are provided on the front surfaces of the power semiconductor elements 12a and 12b. In the case where the power semiconductor elements 12a and 12b are IGBTs, the main electrodes are emitter electrodes. In the case where the power semiconductor elements 12a and 12b are power MOSFETs, the main electrodes are source electrodes. The control electrodes are the gate electrodes of the switching elements included in the power semiconductor elements 12a and 12b.

Although not illustrated, main electrodes are also provided on the rear surfaces of the power semiconductor elements 12a and 12b. In the case where the power semiconductor elements 12a and 12b are IGBTs, the main electrodes on their rear surfaces are collector electrodes. In the case where the power semiconductor elements 12a and 12b are power MOSFETs, the main electrodes on their rear surface are drain electrodes.

Although FIG. 2 illustrates an example in which the two power semiconductor elements 12a and 12b are provided, the configuration is not limited thereto. The number of power semiconductor elements may be determined according to the specifications of the power semiconductor device 10. In addition, other semiconductor elements such as diode elements may be mounted on the insulating circuit substrate 11.

The wiring substrate 14 is provided to face the principal surface of the insulating circuit substrate 11. The wiring substrate 14 includes an insulating plate 14a and wiring pattern layers 14b1, 14b2, 14b3, 14b4, 14b5, and 14b6.

The insulating plate 14a is formed in a rectangular shape having a recess 14c in a part thereof in plan view. Corner portions of the insulating plate 14a may be R-chamfered or C-chamfered. The insulating plate 14a is made of a ceramic material having good thermal conductivity. The ceramic material is, for example, a material containing aluminum oxide, aluminum nitride, or silicon nitride as a main component.

The insulating plate 14a is provided with a plurality of openings, and each of the terminals 15a to 15l are fitted into one of the plurality of openings. The plurality of openings are, for example, through-holes penetrating through the insulating plate 14a from the front surface to the rear surface thereof. Further, the plurality of openings may be through-holes whose inner walls are plated.

Although FIG. 1 illustrates the openings 14d1, 14d2, 14d3, and 14d4 into which terminals are not fitted, terminals may be fitted into these openings 14d1 to 14d4.

The wiring pattern layers 14b1 to 14b6 are provided, for example, on the rear surface (lower surface) of the insulating plate 14a as illustrated in FIG. 2, and are each electrically connected to one of the power semiconductor elements 12a and 12b or to the insulating circuit substrate 11.

Each of the wiring pattern layers 14b1 to 14b6 is electrically connected to one of the power semiconductor elements 12a and 12b or to the insulating circuit substrate 11, for example, via a conductive member. As an example of the conductive members, FIG. 2 illustrates conductive posts 17a, 17b, 17c, 17d, 17e, and 17f, which are pin-shaped conductive members.

For example, the conductive post 17a is electrically and mechanically connected to one of the main electrode and the control electrode on the front surface of the power semiconductor element 12a and to the wiring pattern layer 14b1 by a bonding member. The conductive post 17b is electrically and mechanically connected to the other of the main electrode and the control electrode on the front surface of the power semiconductor element 12a and to the wiring pattern layer 14b2 by a bonding member. The conductive post 17c is electrically and mechanically connected to one of the main electrode and the control electrode on the front surface of the power semiconductor element 12b and to the wiring pattern layer 14b3 by a bonding member. The conductive post 17d is electrically and mechanically connected to the other of the main electrode and the control electrode on the front surface of the power semiconductor element 12b and to the wiring pattern layer 14b4 by a bonding member. The conductive post 17f is electrically and mechanically connected to the circuit pattern 11b2, which is electrically connected to the main electrodes on the rear surfaces of the power semiconductor elements 12a and 12b, and to the wiring pattern layer 14b5 by a bonding member. The conductive post 17e is electrically and mechanically connected to the circuit pattern 11b2 and to the wiring pattern layer 14b6 by a bonding member.

The wiring pattern layers 14b1 to 14b6 and the conductive posts 17a to 17f are made of a metal having excellent conductivity. Such a metal is, for example, copper, aluminum, or an alloy containing at least one of these metals. The surfaces of the wiring pattern layers 14b1 to 14b6 and the conductive posts 17a to 17f may be plated to improve their corrosion resistance. The plating material used in this case is, for example, nickel, a nickel-phosphorus alloy, or a nickel-boron alloy.

The wiring pattern layers 14b1 to 14b6 are formed on the insulating plate 14a by forming a metal plate on the rear surface of the insulating plate 14a and performing etching or another processing on the metal plate. Alternatively, the wiring pattern layers 14b1 to 14b6 cut out from a metal plate in advance may be press-bonded to the rear surface of the insulating plate 14a.

The number of wiring pattern layers 14b1 to 14b6, and their shapes, sizes, and others may be selected as appropriate. The wiring pattern layers may be formed on the front surface of the insulating plate 14a, or may be formed on both the front surface and the rear surface thereof. The wiring substrate 14 may be a multilayer wiring substrate in which wiring pattern layers and insulating layers are alternately stacked.

The wiring substrate 14 as described above preferably overlaps the circuit pattern 11b of the insulating circuit substrate 11 over a large area in plan view. This allows the wiring substrate 14, provided directly above the circuit pattern 11b, to be easily electrically connected to various positions on the circuit pattern 11b via conductive posts or the like.

The terminals 15a to 15l are electrically connected to a plurality of power semiconductor elements. For example, as illustrated in FIG. 2, each of the terminals 15a to 15f is electrically connected to either the main electrode or the control electrode of one of the power semiconductor elements 12a and 12b, and functions as a main terminal or a control terminal.

Although not illustrated, each of the terminals 15g to 15l is electrically connected to either the main electrode or the control electrode of another power semiconductor device, and functions as a main terminal or a control terminal.

All the terminals 15a to 15l are directly connected to the wiring substrate 14 and electrically connected to the plurality of wiring pattern layers 14b1 to 14b6. For example, one end of each of the terminals 15a to 15l is upright with respect to the principal surface of the wiring substrate 14. The other ends of the terminals 15a to 15l are fitted into a plurality of openings of the wiring substrate 14. In the case where the plurality of openings are through-holes, each of the terminals 15a to 15l may be electrically connected to any of the wiring pattern layers 14b1 to 14b6 through the corresponding through-hole. The terminals 15a to 15l may be electrically connected to the wiring pattern layers 14b1 to 14b6 by, for example, a bonding member such as solder.

The terminals 15a to 15f are arranged along a first side of the front surface of the wiring substrate 14 in plan view, and the terminals 15g to 15l are arranged along a second side of the front surface of the wiring substrate 14 opposite to the first side in plan view so as to be disposed apart from the terminals 15a to 15f. Thus, during molding of the encapsulating resin 16, a pressure difference is less likely to occur on the upper surface of the wiring substrate 14, which prevents displacement of the wiring substrate 14.

For example, press-fit pins may be used as the terminals 15a to 15l. The terminals 15a to 15l may be the same as or differ from one another in terms of size, such as thickness and length, and shape.

The encapsulating resin 16 encapsulates the power semiconductor elements 12a and 12b, the insulating circuit substrate 11, the wiring substrate 14, and a part of each of the plurality of terminals 15a to 15l, while leaving one end of each of the plurality of terminals 15a to 15l exposed.

As the material of the encapsulating resin 16, for example, a thermosetting resin such as an epoxy resin, a phenolic resin, or a maleimide resin may be used. The power semiconductor device 10 encapsulated with the encapsulating resin 16 has the metal plate 11c of the insulating circuit substrate 11 exposed at the rear surface thereof. In this case, the metal plate 11c may be flush with the rear surface of the encapsulating resin 16 or may protrude outward from the rear surface.

The encapsulating resin 16 may be formed by resin molding such as transfer molding, for example.

The power semiconductor device 10 may further include a resin holder which is disposed around a part of the outer periphery of each of the plurality of terminals 15a to 15l and whose lower surface is in contact with the wiring substrate 14. FIG. 2 illustrates resin holders 20a, 20b, 20c, 20d, 20e, and 20f which are each disposed around a part of the outer periphery of one of the terminals 15a to 15f and whose lower surfaces are in contact with the wiring substrate 14.

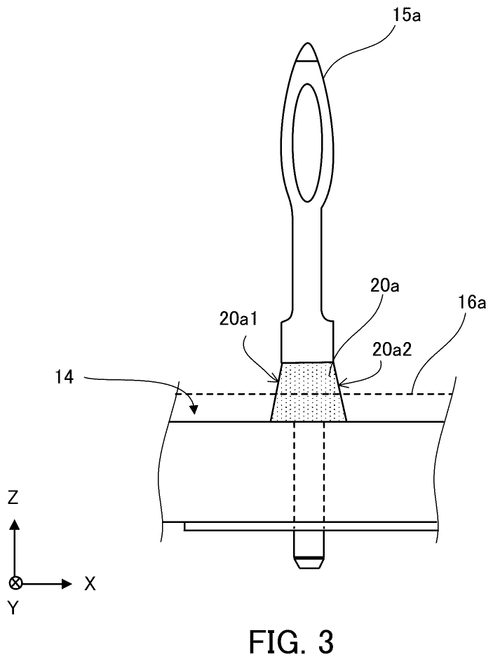

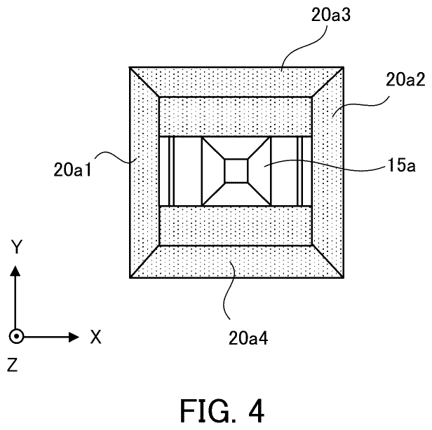

FIG. 3 is an enlarged side view of a connection portion between a terminal and a wiring substrate. FIG. 4 is a top view of the terminal and a resin holder. In FIG. 3, an outer surface 16a of the encapsulating resin 16 is indicated by a broken line. The broken line corresponds to a partition line (or a parting line), which is a line where an upper mold and a lower mold meet during molding of the encapsulating resin 16.

In the example of FIGS. 3 and 4, the resin holder 20a has a truncated quadrangular pyramid shape. The resin holder 20a is disposed around a part of the outer periphery of the terminal 15a, with its lower surface in contact with the wiring substrate 14. The resin holder 20a includes tapered portions 20a1, 20a2, 20a3, and 20a4, which become wider toward the wiring substrate 14, and at least a part of each of the tapered portions 20a1 to 20a4 extends outward from the outer surface 16a of the encapsulating resin 16.

The resin holder 20a having the truncated quadrangular pyramid shape includes four side surfaces, and the four side surfaces are the tapered portions 20a1 to 20a4. The tapered portions 20a1 to 20a4 preferably have a taper angle in the range of 18°to 48°, inclusive. The reason for this will be described later.

As the resin of the resin holder 20a, for example, a material having a Young's modulus in the range of 5 GPa to 20 GPa, inclusive, may be used. As such a resin, for example, a thermoplastic resin such as poly phenylene sulfide (PPS) or polyamide (PA) may be used.

A resin holder similar to the resin holder 20a may be disposed around a part of the outer periphery of each of the other terminals 15b to 15l.

In this connection, the outer shape of the resin holder is not limited to the truncated quadrangular pyramid shape. The outer shape of the resin holder may be a truncated conical shape.

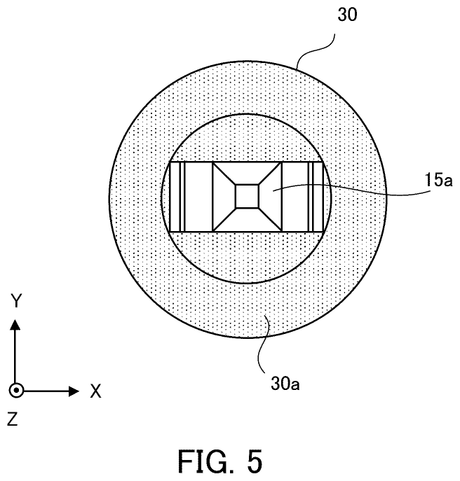

FIG. 5 is a top view of a terminal and a resin holder in the case where the rein holder is formed in a truncated conical shape.

The outer shape of the resin holder 30 is a truncated conical shape. Even in the case where this resin holder 30 is used, its side surface forms a tapered portion 30a. A side view of the resin holder 30 is the same as that of the resin holder 20a illustrated in FIG. 3.

The shape of the resin holder is not limited to those described above. For example, a resin holder having a truncated pyramidal shape, such as a truncated triangular pyramid or a truncated pentagonal pyramid, may be used.

As described above, the power semiconductor device 10 of the present embodiment includes a power semiconductor element (for example, the power semiconductor elements 12a and 12b in FIG. 2) and the insulating circuit substrate 11 having the principal surface on which the power semiconductor element is mounted. The power semiconductor device 10 further includes the wiring substrate 14 provided to face the principal surface of the insulating circuit substrate 11 and having a plurality of wiring pattern layers (for example, the wiring pattern layers 14b1 to 14b6 in FIG. 2) each electrically connected to the power semiconductor element or insulating circuit substrate 11. The power semiconductor device 10 further includes the plurality of terminals 15a to 15l electrically connected to the power semiconductor element, and the encapsulating resin 16. The encapsulating resin 16 encapsulates the power semiconductor element, the insulating circuit substrate 11, the wiring substrate 14, and a part of each of the terminals 15a to 15l while exposing one end of each of the terminals 15a to 15l. Here, all the terminals 15a to 15l are directly connected to the wiring substrate 14 and are electrically connected to the plurality of wiring pattern layers.

As described above, all the terminals 15a to 15l, which are electrically connected to the power semiconductor element, are directly connected to the wiring substrate 14 different from the insulating circuit substrate 11. With this configuration, the reference positions for the arrangement of the terminals 15a to 15l may be determined on the wiring substrate 14, which improves the positional accuracy of the terminals of the power semiconductor device 10.

In addition, the wiring substrate 14 may be disposed closer to the outer surface of the encapsulating resin 16 than is the insulating circuit substrate 11. For example, the distance d (see FIG. 2) from the upper surface of the wiring substrate 14 to the outer surface of the encapsulating resin 16 may be set to 2 mm or less. Thus, when the encapsulating resin 16 is formed using a mold so as to expose one end of each of the terminals 15a to 15l directly connected to the wiring substrate 14, positional displacement of the terminals 15a to 15l due to the force of the resin flowing into the mold is less likely to occur.

In the power semiconductor device 10, one end of each of the plurality of terminals 15a to 15l is upright with respect to the principal surface of the wiring substrate 14. This allows the terminals 15a to 15l to project from the upper surface of the encapsulating resin 16. That is, the terminals are able to have an upward projecting structure.

In order to improve the positional accuracy of the terminals, there is a method of manufacturing a power semiconductor device using a plate-shaped component referred to as a tie bar, to which the terminals are joined. In this method, the tie bar on which semiconductor elements are mounted is sandwiched between an upper mold and a lower mold, with the terminals partially exposed from the encapsulating resin, and transfer molding is performed. After the molding, the joined terminals are individually cut and bent in predetermined directions.

In the case where such a tie bar is used, the power semiconductor device has a structure in which the terminals project from the side surfaces of the encapsulating resin, for reasons related to the above molding. Such a structure allows the thickness of the power semiconductor device to be reduced. However, the structure has the following drawbacks. Since a cooler is provided on the rear surface (the bottom surface of the encapsulating resin) of the power semiconductor device, the creepage distance between each terminal projecting from the side surface and the cooler becomes short. In addition, since the terminals project from the side surfaces, the width of the power semiconductor device is greater than that of the encapsulating resin. Further, even if the terminals projecting from the side surfaces are bent upward and are press-fitted into a printed circuit board on which a gate drive circuit and others are formed for electrical connection, there is a possibility that the terminals do not withstand the pressure because there is no support at the lower portions of the terminals.

Compared with the power semiconductor device in which the terminals project from the side surfaces of the encapsulating resin, the power semiconductor device 10 having the upward protruding structure of the terminals has a long creepage distance between each of the terminals 15a to 15l and a cooler. Further, the power semiconductor device 10 has a smaller width than the power semiconductor device in which the terminals project from the side surfaces. Further, since one end of each of the terminals 15a to 15l is upright with respect to the principal surface of the wiring substrate 14, the terminals 15a to 15l are easily press-fitted into another printed circuit board.

In order to provide a power semiconductor device in which terminals project from the upper surface of an encapsulating resin without strictly controlling the dimensions of internal components or molds, there is a technique using resin sleeves, as disclosed in, for example, Patent Literatures (5) to (7) listed above. In this technique, transfer molding is performed in a state where sleeves are fitted to the upper ends of electrode terminals standing upright on a circuit pattern on the upper surface of an insulating substrate, and external terminals are inserted from the exposed openings of the sleeves so as to come into contact with the electrode terminals. In such a technique, there is a possibility that the creepage distance between the external terminals inserted into the sleeves from above becomes short. In addition, since the external terminals are inserted into the sleeves only by the frictional force of the fitting, there is a possibility that the sleeve length increases and accordingly the height of the power semiconductor device increases. Furthermore, the positioning of the electrode terminals and the sleeves is difficult, and accordingly fitting may be difficult.

Compared with the power semiconductor device using such sleeves, the power semiconductor device 10 of the present embodiment has the terminals 15a to 15l whose ends are fitted into a plurality of openings of the wiring substrate 14, respectively, so that the terminals 15a to 15l are directly connected to the wiring substrate 14. Thus, it is expected that the height of the power semiconductor device 10 is reduced compared to the case of using sleeves.

In addition, the power semiconductor device 10 of the present embodiment further includes resin holders (for example, the resin holders 20a to 20f), each of which is disposed around a part of the outer periphery of one of the terminals 15a to 15l with its lower surface in contact with the wiring substrate 14. By providing such resin holders, the positional accuracy of the terminals 15a to 15l in the Z direction is improved. Further, by providing such resin holders, the creepage distance between the terminals 15a to 15l is increased.

Further, each resin holder includes a tapered portion that becomes wider toward the wiring substrate 14, and at least a part of the tapered portion extends outward from the outer surface of the encapsulating resin 16. The use of such resin holders provides the following effects.

FIG. 6 is a sectional view illustrating terminals and a part of the wiring substrate at the time of transfer molding. In FIG. 6, a lower mold is not illustrated.

Recesses 41a, 41b, and 41c for accommodating the terminals 15d, 15e, and 15f are formed in the upper mold 40. Even if the positions of the terminals 15d to 15f are slightly displaced with respect to the positions of the recesses 41a to 41c, the displacement may be absorbed by the upper mold 40 biting into the tapered portions of the resin holders 20d, 20e, and 20f.

In the example of FIG. 6, the position of the central axis of the terminal 15f is slightly displaced in the +X-axis direction relative to the central axis of the recess 41c. However, since the upper mold 40 bites into the tapered portion of the resin holder 20f, the gap is eliminated, which prevents the resin material from flowing into the recess 41c. That is, resin leakage is prevented.

The terminal 15e is displaced in the Z-axis direction. Similarly, the upper mold 40 bites into the tapered portion of the resin holder 20e, so that the gap is eliminated, which prevents the resin material from flowing into the recess 41b and prevents resin leakage. In this connection, the displacement of a terminal in the Z-axis direction may also occur due to warpage of the wiring substrate 14 or the like.

The following describes results of investigating an appropriate taper angle of the tapered portion. The following example uses the resin holder 20e disposed around a part of the outer periphery of the terminal 15d, but the same applies to the other resin holders.

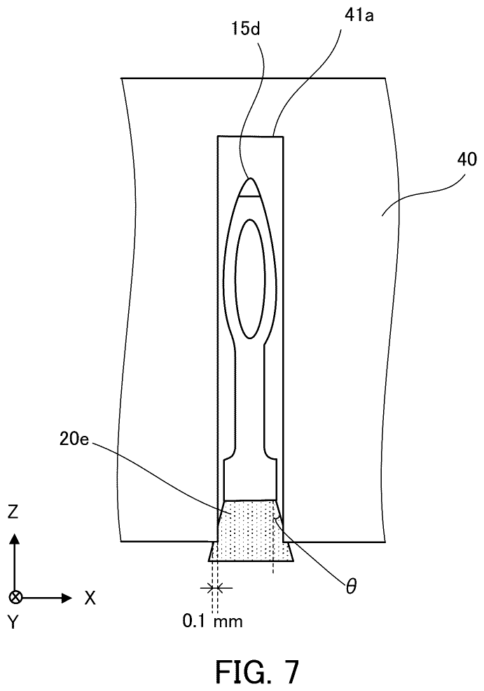

FIG. 7 illustrates how much force is applied by an upper mold onto a resin holder.

In investigating an appropriate taper angle, the force applied by the upper mold 40 onto the resin holder 20e is set so that the upper mold 40 bites into the resin holder 20e by 0.1 mm toward the central axis of the resin holder 20e. In FIG. 7, θ denotes a taper angle.

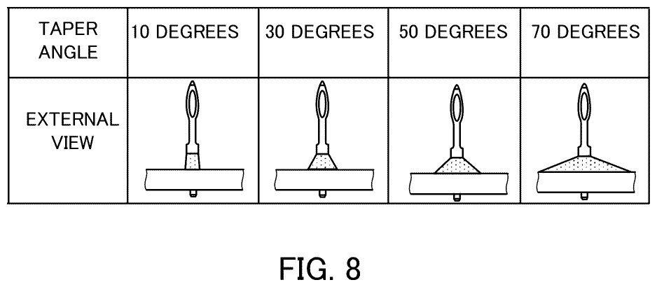

FIG. 8 illustrates examples of a plurality of taper angles and the appearances of the resin holder at the respective taper angles. FIG. 8 illustrates examples of the appearances of the resin holder for the following four taper angles: 10°, 30°, 50°, and 70°.

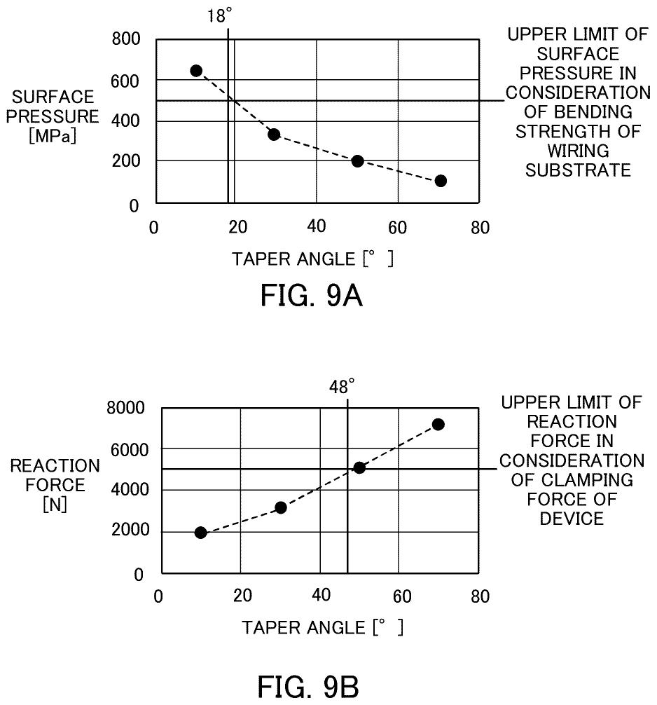

FIGS. 9A and 9B illustrate simulation results of the relationships between taper angle and surface pressure and between taper angle and reaction force. FIG. 9A illustrates the relationship between taper angle and surface pressure, and FIG. 9B illustrates the relationship between taper angle and reaction force.

In the case where the upper mold 40 is pressed against the resin holder 20e such that the upper mold 40 bites into the resin holder 20e by 0.1 mm toward the central axis of the resin holder 20e as illustrated in FIG. 7, the surface pressure applied to the wiring substrate 14 decreases as the taper angle increases as illustrated in FIG. 9A. Considering the bending strength (500 MPa) of the typical wiring substrate 14, the taper angle is preferably 18° or more.

In addition, as the taper angle increases, the reaction force increases as illustrated in FIG. 9B. That is, as illustrated in FIG. 7, the force needed to press the upper mold 40 against the resin holder 20e so that the upper mold 40 bites into the resin holder 20e by 0.1 mm toward the central axis of the resin holder 20e becomes larger. In the case where the clamping force of a transfer molding device is 560 kN, 80% of this force is used, and the number of terminals is set to 12 as in the power semiconductor device 10 of FIGS. 1 and 2, the upper limit of the reaction force in consideration of the clamping force of the transfer molding device is approximately 4.7 kN. Therefore, the taper angle is preferably 48° or less.

From the above investigation results, it is found that the taper angle of the tapered portion of the resin holder is preferably in the range of 18° to 48°, inclusive.

### Method of Manufacturing Power Semiconductor Device

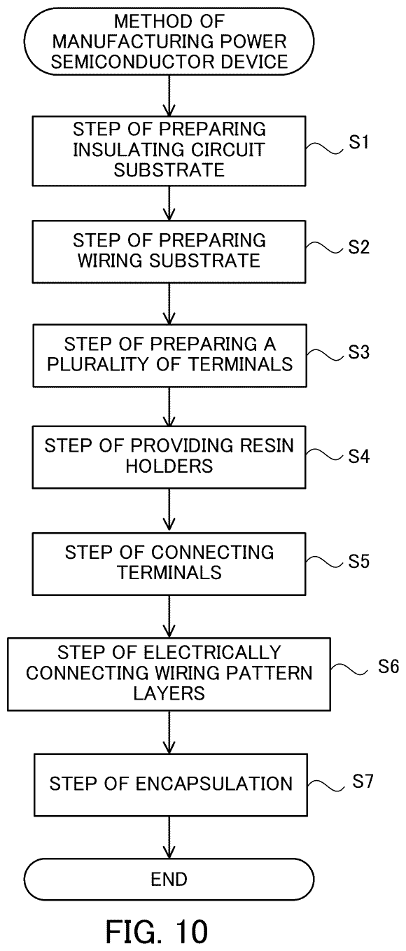

FIG. 10 is a flowchart illustrating an example of a method of manufacturing a power semiconductor device. FIG. 10 illustrates an example of a manufacturing process of the power semiconductor device 10 illustrated in FIGS. 1 and 2.

Step S1: A step of preparing an insulating circuit substrate 11 having a principal surface on which power semiconductor elements (for example, the power semiconductor elements 12a and 12b in FIG. 2) are mounted is executed.

Step S2: A step of preparing a wiring substrate 14 including a plurality of wiring pattern layers (for example, the wiring pattern layers 14b1 to 14b6 in FIG. 2), which are to be electrically connected to the power semiconductor elements or insulating circuit substrate 11, is executed.

Step S3: A step of preparing a plurality of terminals 15a to 15l each having one end linearly extending and the other end provided with a connection portion is executed. The connection portion of each terminal 15a to 15l is a portion that is connected to the wiring substrate 14 (a portion that is inserted into an opening of the wiring substrate 14 in the example of FIG. 2). As these terminals 15a to 15l, press-fit pins may be used.

The terminals 15a to 15l prepared in this step may be prepared as a component in which the terminals are interconnected at intermediate portions between their opposite ends, for example.

Step S4: A step of providing a resin holder around a part of the outer periphery of each of the terminals 15a to 15l is executed. In step S4, the terminals 15a to 15l are set in a mold, and a resin holder is formed around a part of the outer periphery of each of the terminals 15a to 15l by resin molding.

As the resin of the resin holders, for example, a material having a Young's modulus in the range of 5 GPa to 20 GPa, inclusive, may be used. As such a resin, for example, a thermoplastic resin such as PPS or PA may be used.

The resin holders may have, for example, a truncated quadrangular pyramid shape as in the resin holders 20a to 20f illustrated in FIGS. 3 and 4, or may have a truncated conical shape as illustrated in FIG. 5. Note that resin holders having another truncated pyramidal shape, such as a truncated triangular pyramid or a truncated pentagonal pyramid, may be used. Each of the resin holders may include a tapered portion that becomes wider toward the connection portion of the corresponding terminal. The taper angle is preferably in the range of 18° to 48°, inclusive, for the reasons described above.

In the case where the terminals 15a to 15l are interconnected, the terminals 15a to 15l are cut into individual terminals after the resin holders are formed.

Step S5: A step of directly connecting the connection portions of all the terminals 15a to 15l to the wiring substrate 14 and electrically connecting all the terminals 15a to 15l to the plurality of wiring pattern layers of the wiring substrate 14 is executed.

For example, the connection portions of the terminals 15a to 15l are fitted into a plurality of openings of the wiring substrate 14, respectively. In the case where the plurality of openings are through-holes, each of the terminals 15a to 15l is electrically connected to a wiring pattern layer (for example, the wiring pattern layers 14b1 to 14b6 in FIG. 2) through the corresponding through-hole. The terminals 15a to 15l may be electrically connected to the wiring pattern layers by, for example, a bonding member such as solder.

Step S6: A step is executed in which the wiring substrate 14 having the terminals 15a to 15l connected thereto is disposed to face the principal surface of the insulating circuit substrate 11, and then each of the plurality of wiring pattern layers (for example, the wiring pattern layers 14b1 to 14b6 in FIG. 2) of the wiring substrate 14 is electrically connected to one of the power semiconductor elements (for example, power semiconductor elements 12a and 12b in FIG. 2) or to the insulating circuit substrate 11.

Each of the plurality of wiring pattern layers is electrically connected to one of the power semiconductor elements 12a and 12b or to the insulating circuit substrate 11, for example, via a conductive member. As the conductive members, for example, the conductive posts 17a to 17f as illustrated in FIG. 2 may be used.

Step S7: A step of encapsulating the power semiconductor elements, the insulating circuit substrate 11, the wiring substrate 14, and a part of each of the terminals 15a to 15l with a resin, with one end of each of the terminals 15a to 15l being exposed, is executed. As a result of step S7, the encapsulating resin 16 as illustrated in FIG. 2 is formed. The encapsulating resin 16 may be formed by transfer molding.

The power semiconductor device 10 is manufactured through the steps described above.

The power semiconductor device and the method of manufacturing the same according to the present disclosure have been described above with reference to the embodiment. However, the description is merely an example, and these are not limited to the above description.

For example, one end of each of the plurality of terminals directly connected to the wiring substrate 14 may be exposed from the side surfaces of the encapsulating resin 16. In this case, each terminal may have, for example, a portion extending perpendicular to the principal surface of the wiring substrate 14 and a portion extending parallel to the principal surface.

According to the disclosed techniques, the positional accuracy of terminals of a power semiconductor device is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A power semiconductor device, comprising:
a power semiconductor element;
an insulating circuit substrate having a principal surface on which the power semiconductor element is mounted;
a wiring substrate disposed to face the principal surface of the insulating circuit substrate, the wiring substrate including a plurality of wiring pattern layers each electrically connected to the power semiconductor element or to the insulating circuit substrate;
a plurality of terminals electrically connected to the power semiconductor element, each terminal having a first end and a second end;
an encapsulating resin encapsulating the power semiconductor element, the insulating circuit substrate, the wiring substrate, and a part of each of the plurality of terminals with the first end of each of the plurality of terminals exposed; and
a plurality of resin holders respectively for the plurality of terminals, each resin holder being disposed around a part of an outer periphery of the corresponding one of the plurality of terminals, and having a lower surface in contact with the wiring substrate,
wherein all of the plurality of terminals are directly connected to the wiring substrate, and are electrically connected to the plurality of wiring pattern layers.

2. The power semiconductor device according to claim 1, wherein the first end of each of the plurality of terminals is upright with respect to the principal surface of the wiring substrate.

3. The power semiconductor device according to claim 1, wherein
the wiring substrate has a plurality of openings, and
the second ends of the plurality of terminals are fitted into the plurality of openings, respectively.

4. The power semiconductor device according to claim 1, wherein
each of the plurality of resin holders includes a tapered portion with a width thereof increasing toward the wiring substrate, and
at least a part of the tapered portion extends outward from an outer surface of the encapsulating resin.

5. The power semiconductor device according to claim 4, wherein the tapered portion has a taper angle in a range from 18° to 48°, inclusive.

6. The power semiconductor device according to claim 1, wherein each of the plurality of resin holders includes a resin having a Young's modulus in a range from 5 GPa to 20 GPa, inclusive.

7. The power semiconductor device according to claim 1, wherein in a direction perpendicular to the principal surface of the wiring substrate, a distance from an upper surface of the wiring substrate to an outer surface of the encapsulating resin is 2 mm or less.

8. A method of manufacturing a power semiconductor device, the method comprising:
preparing an insulating circuit substrate having a principal surface on which a power semiconductor element is mounted;
preparing a wiring substrate including a plurality of wiring pattern layers;
preparing a plurality of terminals each having a first end linearly extending and a second end provided with a connection portion;
directly connecting the connection portions of all of the plurality of terminals to the wiring substrate, and electrically connecting all of the plurality of terminals to the plurality of wiring pattern layers;
disposing the wiring substrate, with the plurality of terminals connected thereto, to face the principal surface of the insulating circuit substrate, and electrically connecting the plurality of wiring pattern layers to the power semiconductor element or to the insulating circuit substrate;
encapsulating the power semiconductor element, the insulating circuit substrate, the wiring substrate, and a part of each of the plurality of terminals with a resin, with the first end of each of the plurality of terminals exposed; and
providing a resin holder around a part of an outer periphery of each of the plurality of terminals,
wherein the plurality of terminals are disposed on the wiring substrate such that lower surfaces of the resin holders are in contact with the wiring substrate.

9. The method of manufacturing the power semiconductor device according to claim 8, wherein the first end of each of the plurality of terminals is upright with respect to the principal surface of the wiring substrate.

10. The method of manufacturing the power semiconductor device according to claim 8, wherein
the wiring substrate has a plurality of openings, and
the second ends of the plurality of terminals are fitted into the plurality of openings, respectively.

11. The method of manufacturing the power semiconductor device according to claim 8, wherein
each of the resin holders includes a tapered portion with a width thereof increasing toward the wiring substrate, and
at least a part of the tapered portion extends outward from an outer surface of an encapsulating resin.

12. The method of manufacturing the power semiconductor device according to claim 11, wherein the tapered portion has a taper angle in a range from 18° to 48°, inclusive.

13. The method of manufacturing the power semiconductor device according to claim 8, wherein the resin holders each include a resin having a Young's modulus in a range from 5 GPa to 20 GPa, inclusive.
